(19) United States
(12) Patent Application Publication
(10) Pub. No.: US 2024/0292643 A1
(43) Pub. Date: Aug. 29, 2024

(54) QUANTUM DOT LIGHT EMITTING DIODE DEVICE, MANUFACTURING METHOD THEREOF, AND DISPLAY PANEL

(71) Applicant: TCL Technology Group Corporation, Huizhou, Guangdong (CN)

(72) Inventor: Jing WANG, Huizhou, Guangdong (CN)

(73) Assignee: TCL Technology Group Corporation, Huizhou, Guangdong (CN)

(21) Appl. No.: 18/570,092

(22) PCT Filed: Sep. 27, 2022
(86) PCT No.: PCT/CN2022/121786

§ 371 Date: Dec. 14, 2023

(30) Foreign Application Priority Data
Sep. 30, 2021 (CN) 202111164887.4

(51) Int. Cl. H10K 50/115; H10K 50/15; H10K 50/16; H10K 71/60; H10K 85/40; H10K 85/60

(52) U.S. Cl. CPC H10K 50/115; H10K 50/15; H10K 50/16; H10K 71/60; H10K 85/40; H10K 85/611

(57) ABSTRACT

Disclosed are a quantum dot light emitting diode device a method for manufacturing the same, and a display panel. The quantum dot light emitting diode device includes a functional layer and a quantum dot light emitting layer, and a self-assembled molecular layer is disposed between the functional layer and the quantum dot light emitting layer. A force is generated between the self-assembled molecular layer and the functional layer to improve the bonding force between the functional layer and the quantum dot light emitting layer, thereby improving the mechanical reliability of an interface.

This application claims priority to Chinese Patent Application No. 202111164887.4, filed in the China National Intellectual Property Administration on Sep. 30, 2021, and entitled “QUANTUM DOT LIGHT EMITTING DIODE DEVICE AND DISPLAY PANEL”, which is incorporated herein by reference in its entirety.

### TECHNICAL FIELD

The present disclosure relates to a field of display technologies, and more particularly, to a quantum dot light emitting diode device, a manufacturing method thereof, and a display panel.

### BACKGROUND

Semiconductor quantum dots (QDs) are characterized by high fluorescence quantum efficiency, adjustable light emission in the visible light band, wide color gamut coverage, and the like, and have attracted great attention in the field of display and solid state illumination. Compared with the conventional display technology, an electroluminescent device based on quantum dot technology, i.e., the quantum dot light emitting diode (QLED) device, has advantages such as high stability, solution-processability, high color saturation, and the like, and can realize a leap from a point light source to a surface light source by self-luminescence.

The QLED device is a thin film stack structure similar to a “sandwich” formed by two electrodes and the addition of various functional layers between the electrodes and the quantum dots. These functional layers include an electron injection layer, an electron transport layer, a hole transport layer, a hole injection layer, and the like. The film-forming quality of each thin film layer, the interface bonding, and the stability of the material itself may greatly affect the performance of the device. Current QLED devices and related materials are mostly prepared at low temperatures (<300° C.), resulting in a corresponding reduction in equipment requirements, which facilitates process simplification and cost reduction.

### SUMMARY

### Technical Problem

For an electron transport layer material formed by a low-temperature method, there are many surface defects, low electron mobility, and uneven film formation and pinholes are prone to occur during the film forming process. Common organic hole transport materials are mainly biphenyl-based material, poly/bithiophene-based material, triarylamine-based material, carbazole-based material, pyrazoline-based material, butadiene-based material, styrene-based material, and the like, which have disadvantages such as poor environmental stability, poor high temperature resistance, and low hole mobility. In addition, the functional thin film layer and the quantum dot light-emitting layer are adhered to each other. However, based on the differences in material types and characteristics of the organic hole transport material, the inorganic quantum dot material and the inorganic electron transport material, there is a problem that the bonding between the functional thin film layer and the quantum dot light emitting layer is poor. In particular, in the process of forming the QLED device based on the solution method, there is a problem of erosion and damage of the solvent of the upper thin film layer material to the lower thin film layer, which may negatively affect the film quality of the lower thin film layer, and is not conducive to the bonding between the upper thin film layer and the lower thin film layer, thereby seriously reducing the device performance.

Accordingly, there is an urgent need to provide a quantum dot light emitting diode device that may improve the bonding between the functional thin film layer and the quantum dot light emitting layer.

### Technical Solution

In view of this, the present application provides a quantum dot light-emitting diode device, a method for manufacturing the same, and a display panel, which can improve the bonding between a functional thin film layer and a quantum dot light-emitting layer.

According to a first aspect, the present disclosure provides a quantum dot light emitting diode device including a first electrode, a hole functional layer, a quantum dot light emitting layer, an electron functional layer, and a second electrode, which are sequentially stacked. There is a self-assembled molecular layer arranged between the hole functional layer and the quantum dot light emitting layer, or there is a self-assembled molecular layer arranged between the electron functional layer and the quantum dot light emitting layer, or there are self-assembled molecular layers arranged between the hole functional layer and the quantum dot light emitting layer and between the electron functional layer and the quantum dot light emitting layer respectively.

Alternatively, the hole functional layer includes a hole injection layer and/or a hole transport layer.

The electron functional layer includes an electron injection layer and/or an electron transport layer.

Alternatively, the self-assembled molecular layer between the hole functional layer and the quantum dot light emitting layer includes a compound having a structure represented by a general formula (R₁)₃NR₂X.

In the general formula (R₁)₃NR₂X, R₁ is methyl or ethyl, N is a positively charged tetravalent nitrogen, X is a halogen anion or carboxylate, R₂ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₂ ranges from 4 to 20.

Alternatively, there is an electrostatic adsorption force between the positively charged tetravalent nitrogen and unsaturated bonds in the hole functional layer.

There is a van der Waals force or a hydrogen bond formed between the R₂ and a ligand of a quantum dot of the quantum dot light emitting layer, or there is a coordination bond formed between the R₂ and a quantum dot of the quantum dot light emitting layer.

Alternatively, the compound having the structure represented by the general formula (R₁)₃NR₂X is selected from:

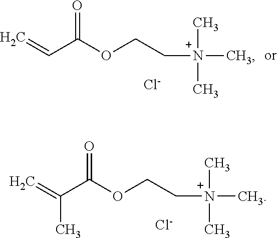

Alternatively, the self-assembled molecular layer between the hole functional layer and the quantum dot light emitting layer includes a compound having a structure represented by the general formula R₃-R₄.

In the general formula R₃-R₄, R₃ is a phenol group or a catechol group; R₄ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₄ ranges from 4 to 20.

Alternatively, the R₃ forms a hydrogen bond with a surface of the hole functional layer such that the self-assembled molecular layer is bonded to the surface of the hole functional layer.

There is a van der Waals force or a hydrogen bond between the R₄ and a ligand of a quantum dot of the quantum dot light emitting layer, or there is a coordination bond is formed between the R4 and the quantum dot of the quantum dot light emitting layer, such that the self-assembled molecular layer is bonded to a surface of the quantum dot light emitting layer.

Alternatively, the compound having the structure represented by the general formula R3-R4 is selected from:

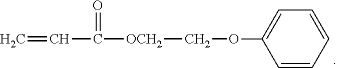

Alternatively, the self-assembled molecular layer between the quantum dot light emitting layer and the electron functional layer includes a compound having a structure represented by the general formula R₅-R₆.

In the general formula R₅-R₆, R₅ is selected from one or more of an amino group, sulfhydryl, carboxyl, hydroxyl, carbonyl, an amide group, phosphorus, phosphorusoxy, organophosphorus, a thioether group, or a polysiloxane group, R₆ is selected from one or more of hydrocarbyl, hydrocarbyl containing an aryl group, or an ether group, a polyoxypropylene group, or a perfluoroalkyl group, and a number of carbon atoms of R₆ ranges from 4 to 20.

Alternatively, there is a coordination bond formed between the R5 and a quantum dot of the quantum dot light emitting layer, or there is a hydrogen bond formed between the R5 and a surface ligand of the quantum dot of the quantum dot light emitting layer, such that the self-assembled molecular layer is bonded to a surface of the quantum dot light emitting layer.

There is a van der Waals force between the R₆ and a surface of the electronic functional layer, so that the self-assembled molecular layer is adsorbed to the surface of the electronic functional layer.

Alternatively, the compound having the structure of Formula R5-R6 is selected from:

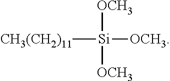

Alternatively, the thickness of the self-assembled molecular layer ranges from 1 nm to 50 nm.

Alternatively, the functional layer includes a hole transport layer including an organic hole transport material, the organic hole transport material includes one or more of biphenyl-based material, poly/bithiophene-based material, triarylamine-based material, carbazole-based material, pyrazoline-based material, butadiene-based material, or styrene-based material.

Alternatively, the functional layer includes an electron transport layer, the electron transport layer includes an inorganic nanoparticle material, and the inorganic nanoparticle includes one or more of doped or undoped metal oxides.

Preferably, the doped or undoped metal oxides include one or more of ZnO, TiO₂, SnO₂, Ta₂O₃, ZrO₂, TiLiO, ZnAlO, ZnMgO, ZnSnO, ZnLiO, or InSnO.

Alternatively, the quantum dot light emitting layer includes a quantum dot, the quantum dot includes one or more of a Group II-VI compound or a Group III-V compound, preferably, the quantum dot includes one or more of CdS, CdSe, CdTe, ZnS, ZnSe, ZnTe, GaAs, GaP, GaSb, HgS, HgSe, HgTe, InAs, InP, InSb, AlAs, AlP, CuInS, or CuInSe.

In a second aspect, the present disclosure provides a method of manufacturing a quantum dot light emitting diode device, the method includes the following steps.

A substrate on which a first electrode is formed is provided.

A hole functional layer is formed on the first electrode.

A quantum dot light emitting layer is formed on the hole functional layer.

An electronic functional layer is formed on the quantum dot light emitting layer.

A second electrode is formed on the electronic functional layer.

Alternatively, the method includes the following steps.

A substrate on which a second electrode is formed is provided.

An electronic functional layer is formed on the second electrode.

A quantum dot light emitting layer is formed on the electronic functional layer.

A hole functional layer is formed on the quantum dot light emitting layer.

A first electrode is formed on the hole functional layer.

There is a self-assembled molecular layer arranged between the hole functional layer and the quantum dot light emitting layer, or there is a self-assembled molecular layer arranged between the electron functional layer and the quantum dot light emitting layer, or there are self-assembled molecular layers arranged between the hole functional layer and the quantum dot light emitting layer and between the electron functional layer and the quantum dot light emitting layer respectively.

Alternatively, the self-assembled molecular layer between the hole functional layer and the quantum dot light emitting layer includes a compound having a structure represented by the general formula (R₁)₃NR₂X.

In the general formula (R₁)₃NR₂X, R₁ is methyl or ethyl, N is a positively charged tetravalent nitrogen, X is a halogen anion or carboxylate, R₂ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₂ ranges from 4 to 20.

Alternatively, the self-assembled molecular layer between the hole functional layer and the quantum dot light emitting layer includes a compound having a structure represented by the general formula R₃-R₄, in which R₃ is a phenol group or a catechol group; R₄ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₄ ranges from 4 to 20.

Alternatively, the self-assembled molecular layer between the quantum dot light emitting layer and the electron functional layer includes a compound having a structure represented by the general formula R₅-R₆.

In the general formula R₅-R₆, R₅ is selected from one or more of an amino group, sulfhydryl, carboxyl, hydroxyl, carbonyl, an amide group, phosphorus, phosphorusoxy, organophosphorus, a thioether group, or a polysiloxane group, R₆ is selected from one or more of hydrocarbyl, hydrocarbyl containing an aryl group, or an ether group, a polyoxypropylene group, or a perfluoroalkyl group, and a number of carbon atoms of R₆ ranges from 4 to 20.

According to a third aspect, the present disclosure provides a display panel including a substrate and quantum dot light emitting diode devices disposed on a surface of the substrate in an array, and each of the quantum dot light emitting diode devices comprises a first electrode, a hole functional layer, a quantum dot light emitting layer, an electron functional layer, and a second electrode that are stacked in sequence. There is a self-assembled molecular layer arranged between the hole functional layer and the quantum dot light emitting layer, or there is a self-assembled molecular layer arranged between the electron functional layer and the quantum dot light emitting layer, or there are self-assembled molecular layers arranged between the hole functional layer and the quantum dot light emitting layer and between the electron functional layer and the quantum dot light emitting layer respectively.

Alternatively, the self-assembled molecular layer between the hole functional layer and the quantum dot light emitting layer includes a compound having a structure represented by a general formula (R₁)₃NR₂X, in which R₁ is methyl or ethyl, N is a positively charged tetravalent nitrogen, X is a halogen anion or carboxylate, R₂ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₂ ranges from 4 to 20.

Alternatively, the self-assembled molecular layer between the hole functional layer and the quantum dot light emitting layer includes a compound having a structure represented by the general formula R₃-R₄, in which R₃ is a phenol group or a catechol group; R₄ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₄ ranges from 4 to 20.

Alternatively, the self-assembled molecular layer between the quantum dot light emitting layer and the electron functional layer includes a compound having a structure represented by the general formula R₅-R₆, in which R₅ is selected from one or more of an amino group, sulfhydryl, carboxyl, hydroxyl, carbonyl, an amide group, phosphorus, phosphorusoxy, organophosphorus, a thioether group, or a polysiloxane group, R₆ is selected from one or more of hydrocarbyl, hydrocarbyl containing an aryl group, or an ether group, a polyoxypropylene group, or a perfluoroalkyl group, and a number of carbon atoms of R₆ ranges from 4 to 20.

### Beneficial Effect

The present disclosure provides a quantum dot light emitting diode device (QLED) in which a self-assembled molecular layer is provided between a functional layer and a quantum dot light emitting layer, and the self-assembled molecular layer can effectively improve the adhesion between a hole functional layer and the quantum dot light emitting layer and/or the adhesion between an electron functional layer and the quantum dot light emitting layer, thereby improving the mechanical reliability of an interface.

In the present disclosure, the forces (such as van der Waals forces, coordination bonds, and hydrogen bonds) between the self-assembled molecular layer and the organic hole transport layer, the quantum dot light emitting layer, and the electron transport layer are used, so as to effectively improve the problem that the solvent of the upper-layer thin film material erodes and destroys the lower-layer thin film in the manufacturing process, and the adhesion at the interface between the functional layer and the quantum dot light emitting layer, improve the mechanical reliability of the interface, and improving the problem that the binding force at the interface is poor due to the difference in the material types and characteristics of the organic hole transport material, the inorganic quantum dot material, and the inorganic electron transport material.

### BRIEF DESCRIPTION OF FIGURES

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a first schematic structure diagram of a quantum dot light emitting diode device according to an embodiment of the present disclosure.

FIG. 2 is a second schematic structure diagram of a quantum dot light emitting diode device according to an embodiment of the present disclosure.

FIG. 3 is a schematic structure diagram of a display panel according to an embodiment of the present disclosure.

FIG. 4 is a schematic structure diagram of a quantum dot light emitting diode device according to Embodiment 1 and Embodiment 2 of the present disclosure.

FIG. 5 is a schematic structure diagram of a quantum dot light emitting diode device according to Example 3 of the present disclosure.

FIG. 6 is a schematic structure diagram of a quantum dot light emitting diode device according to Comparative Example 1 of the present disclosure.

FIG. 7 is a graph of current efficiency versus current density characteristics in Test Example 1 of the present disclosure.

FIG. 8 is a schematic structure diagram of a fluorescent thin film in Test Example 2 of the present disclosure.

FIG. 9 is a graph of relative fluorescence intensity of the fluorescent thin film in Test Example 2 of the present disclosure.

FIG. 10 is an AFM diagram in Test Example 2 of the present disclosure.

FIG. 11 is a schematic structure diagram of a fluorescent thin film in Test Example 3 of the present disclosure.

FIG. 12 is a graph of relative fluorescence intensity of the fluorescent thin film in Test Example 3 of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The embodiments of the present disclosure provide a quantum dot light emitting diode device, a manufacturing method thereof and a display panel. Detailed descriptions are given below. It should be noted that the order in which the following embodiments are described is not intended to limit the preferred order of the embodiments.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

An embodiment of the present application provides a quantum dot light emitting diode device including a first electrode, a hole functional layer, a quantum dot light emitting layer, an electron functional layer, and a second electrode, which are sequentially stacked. A self-assembled molecular layer is arranged between the hole functional layer and the quantum dot light emitting layer and/or between the electron functional layer and the quantum dot light emitting layer. A force may be generated between the self-assembled molecular layer and the hole functional layer and/or between the self-assembled molecular layer and the electron functional layer to enhance the bonding between the quantum dot light emitting layer and the hole functional layer and/or between the quantum dot light emitting layer and the electron functional layer. Specifically, the force is selected from one or more of a van der Waals force, a coordination bond, or a hydrogen bond. Further, the self-assembled molecular layer may be a self-assembled monomolecular layer (SAM), which refers to an ordered monomolecular film formed by spontaneous assembly of molecules having active groups on a solid surface.

The hole functional layer includes a hole injection layer and/or a hole transport layer. The electron functional layer comprises an electron injection layer and/or an electron transport layer. For example, the quantum dot light emitting diode device includes a first electrode, a hole transport layer, a quantum dot light emitting layer, an electron transport layer, and a second electrode that are stacked in sequence. For example, the quantum dot light emitting diode device includes a first electrode, a hole injection layer, a hole transport layer, a quantum dot light emitting layer, an electron transport layer, an electron injection layer, and a second electrode that are stacked in sequence. Further, there is a self-assembled molecular layer between the quantum dot light emitting layer and the hole transport layer, and/or there is a self-assembled molecular layer between the quantum dot light emitting layer and the electron transport layer. For example, the self-assembled molecular layer is disposed between the quantum dot light emitting layer and the hole transport layer, and/or the self-assembled molecular layer is disposed between the quantum dot light emitting layer and the electron transport layer. By providing the self-assembled molecular layer in the quantum dot light emitting diode device, the degree of adhesion between the hole transport layer and the quantum dot light emitting layer and/or the degree of adhesion between the electron transport layer and the quantum dot light emitting layer may be effectively improved, thereby improving the mechanical reliability of the interface.

Further, a thickness of the self-assembled molecular layer may range from 1 nm to 50 nm, for example, 1 nm, 3 nm, 5 nm, 10 nm, 15 nm, 20 nm, 25 nm, 30 nm, 35 nm, 40 nm, 45 nm, or 50 nm.

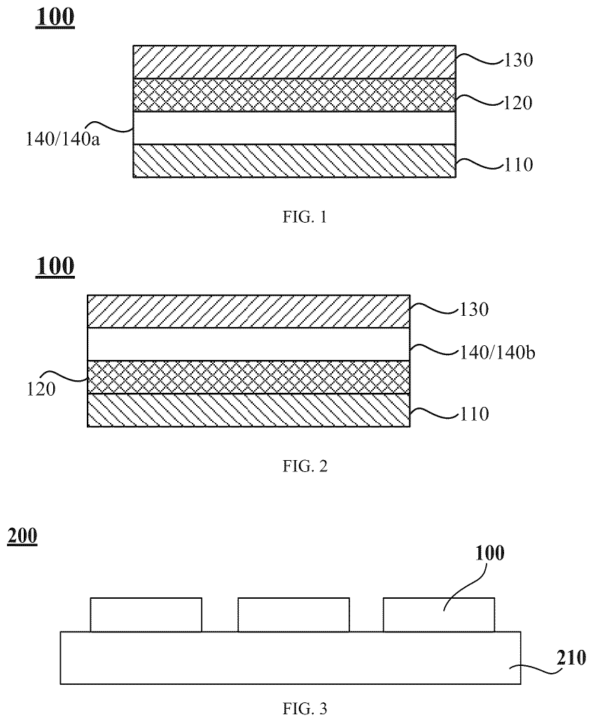

Further, referring to FIGS. 1 and 2, the quantum dot light emitting diode device 100 includes a hole transport layer 110, a quantum dot light emitting layer 120, and an electron transport layer 130, and a self-assembled molecular layer 140 is disposed between the hole transport layer 110 and the electron transport layer 130. For example, with continued reference to FIG. 1, a self-assembled molecular layer 140a is disposed between the hole transport layer 110 and the quantum dot light emitting layer 120. For example, with continued reference to FIG. 2, a self-assembled molecular layer 140b is disposed between the quantum dot light emitting layer 120 and the electron transport layer 130. It is conceivable that the self-assembled molecular layer 140a is provided between the hole transport layer 110 and the quantum dot light emitting layer 120, and that the self-assembled molecular layer 140b is provided between the quantum dot light emitting layer 120 and the electron transport layer 130. The self-assembled molecular layer has a force with the hole transport layer and the electron transport layer.

Further, the self-assembled molecular layer material may be (R₁)₃NR₂X, R₃-R₄, or R₅-R₆. The material may be selected according to the specific location of the self-assembled molecular layer. The selection of the self-assembled molecular layer may be referred to the following description.

In some embodiments, the self-assembled molecular layer between the hole transport layer and the quantum dot light emitting layer includes a structure represented by the general formula (R₁)₃NR₂X, in which:
R₁ is methyl or ethyl, (R₁)₃ refers to three R₁ groups;
N is a positively charged tetravalent nitrogen;
X is a halogen anion (F⁻, Cl⁻, Br⁻, I⁻) or carboxylate (RCOO⁻), where R in RCOO⁻ is a hydrocarbyl group;
R₂ is selected from but not limited to hydrocarbyl, hydrocarbyl containing an aryl group, hydroxy, sulfhydryl, an ester group, an ether group, an amine group (a primary amine, a secondary amine, a tertiary amine), an amide group, phosphorus, phosphorusoxy, a thioether group, and the like, a polyoxypropenyl group, a perfluoroalkyl group, or a polysiloxanyl group, and the like. Preferably, the number of carbon atoms in R₂ is C₄˜C₂₀. Further, depending on the choice of R₂ group and quantum dot ligand species, the binding capacities of both are ordered as: coordination bond>hydrogen bond>van der waals force.

In the present disclosure, the self-assembled molecular layer is electrostatically adsorbed to the surface of the hole transport layer though a positively charged tetravalent nitrogen and an unsaturated bond (such as a benzene ring, a carbon-carbon double bond) in the hole transport layer. The self-assembled molecular layer is bonded to the surface of the quantum dot light emitting layer through R₂ via van der Waals force, or through coordination bonds with quantum dots, or through hydrogen bonds with surface ligands of the quantum dot. The R₂ is bonded to the ligand of the quantum dot through van der Waals force or hydrogen bond, or the R₂ is bonded to the quantum dot through coordination bond.

For example, the (R₁)₃NR₂X may employ acryloyloxyethyl trimethyl ammonium chloride (see formula 1) or methacryloyloxyethyl trimethyl ammonium chloride (see formula 2).

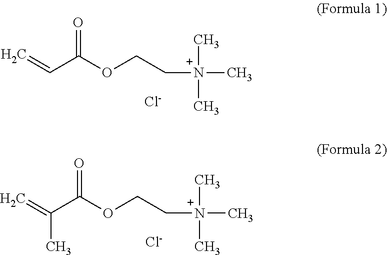

In some embodiments, the self-assembled molecular layer between the hole transport layer and the quantum dot light emitting layer includes a structure represented by the general formula R₃-R₄, in which:
R3 is a phenol group or a catechol group;
R4 is selected from but not limited to hydrocarbyl, hydrocarbyl containing an aryl group, hydroxy, sulfhydryl, an ester group, an ether group, an amine group (a primary amine, a secondary amine, a tertiary amine), an amide group, phosphorus, phosphorusoxy, a thioether group, or the like, a polyoxypropenyl group, a perfluoroalkyl group, a polysiloxanyl group, or the like. Preferably, the number of carbon atoms in R4 is C₄˜C₂₀.

In the present application, the R₃ and the surface of the hole transport layer may form a hydrogen bond such that the self-assembled molecular layer is bonded to the surface of the hole transport layer. The R₄ and the quantum dot have a van der Waals force or form a coordination bond, or a hydrogen bond is formed between the R4 and a surface ligand of the quantum dot, such that the self-assembled molecular layer is bonded to a surface of the quantum dot light emitting layer.

For example, the R₃-R₄ may be 2-phenolethoxy acrylate (see formula 3).

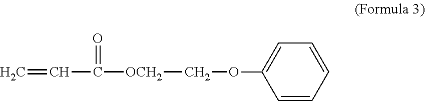

In some embodiments, the self-assembled molecular layer between the quantum dot light emitting layer and the electron transport layer includes a structure represented by the general formula R₅-R₆, in which:

R₅ is selected from, but not limited to, an amino group, sulfhydryl, carboxyl, hydroxyl, carbonyl, an amide group, phosphorus, phosphorusoxy, organophosphorus, a thioether group, a polysiloxane group, or the like;

R₆ is selected from, but not limited to, a hydrocarbyl group, a hydrocarbyl group containing an aryl group, an ether group, or the like, a polyoxypropylene group, a perfluoroalkyl group, or the like. Preferably, the number of carbon atoms in R₆ is C₄˜C₂₀.

In the present disclosure, the R₅ is bonded to the surface of the quantum dot light emitting layer through the coordination bond between the R5 and the quantum dot in the light emitting layer, or the R5 is bonded to the surface of the quantum dot light emitting layer through a hydrogen bond between the R5 and the surface ligand of the quantum dots. The R6 is adsorbed to the surface of the electron transport layer by van der Waals force.

For example, the R₅-R₆ may be dodecyltrimethoxysilane (see formula 4).

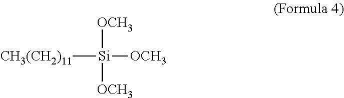

In some embodiments, the hole transport layer includes an organic hole transport material. The organic hole transport material includes, but is not limited to, one or more of biphenyl-based material, poly/bithiophene-based material, triarylamine-based material, carbazole-based material, pyrazoline-based material, butadiene-based material, or styrene-based material.

In some embodiments, the quantum dot light emitting layer includes quantum dots. The quantum dots include one or more of a group II-VI compound or a group III-V compound. Further, the group II-VI compounds may be such as CdS, CdSe, CdTe, ZnS, ZnSe, ZnTe, HgS, HgSe, HgTe, PbS, PbSe, PbTe, or other binary, ternary, or quaternary II-VI compounds; the III-V compounds may be such as GaP, GaAs, InP, InAs, or other binary, ternary, or quaternary III-V compounds. Further, the quantum dot is quantum dot nanoparticle material. For example, the quantum dot is selected from, but is not limited to, one or more of CdS, CdSe, CdTe, ZnO, ZnS, ZnSe, ZnTe, GaAs, GaP, GaSb, HgS, HgSe, HgTe, InAs, InP, InSb, AlAs, AlP, CuInS, or CuInSe, and at least one of various core-shell structure quantum dots.

In some embodiments, the electronic functional layer includes, but is not limited to, inorganic nanoparticle materials having electron transport capabilities. The inorganic nanoparticles include one or more of doped or undoped metal oxides. Further, the doped or undoped metal oxide includes, but is not limited to, one or more of ZnO, TiO₂, SnO₂, Ta₂O₃, ZrO₂, TiLiO, ZnAlO, ZnMgO, ZnSnO, ZnLiO, or InSnO.

An embodiment of the present disclosure further provides a display panel including the quantum dot light emitting diode device described above. As shown in FIG. 3, the display panel 200 includes a substrate 210 on which a plurality of the organic electroluminescent devices 100 are formed. It may be appreciated by those skilled in the art that the substrate 210 may also be provided with structures that have been subjected to the preceding steps, such as, inorganic thin film layers, several thin film layers in a thin film transistor structure, or complete thin film transistors and wires that have been formed. Of course, the display panel 200 also includes other known structures such as a package cover plate, and details are not described herein.

An embodiment of the present disclosure further provides a display device including the display panel described above.

The present disclosure has been subjected to several tests successively, now a part of the test results are taken as a reference to further describe the application in detail, and the present disclosure will be described in detail below with reference to specific examples.

### Example 1

This example provides a quantum dot light emitting diode (QLED) device. Referring to FIG. 4, the QLED device includes an anode, a hole injection layer, a hole transport layer, a self-assembled molecular layer, a quantum dot light emitting layer, an electron transport layer, and a cathode, which are sequentially stacked on a substrate. The material of the self-assembled molecular layer is (R₁)₃NR₂X, specifically acryloyloxyethyl trimethyl ammonium chloride, and the formula is:

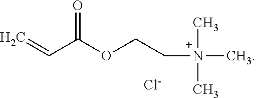

The manufacturing method of the quantum dot light emitting diode device includes the following steps.

A substrate was provided, and an anode is formed on the substrate.

A hole injection layer was formed on the anode.

A hole transport layer was formed on the hole injection layer.

A self-assembled molecular layer was formed on the hole transport layer, and a material of the self-assembled molecular layer was (R₁)₃NR₂X.

A quantum dot light emitting layer was formed on the self-assembled molecular layer.

An electron transport layer was formed on the quantum dot light emitting layer.

A cathode was formed on the electron transport layer.

In the quantum dot light emitting diode device of this example, in addition to the substrate, the anode, and the cathode, the thin film deposition of each of other functional layers was realized by printing.

### Example 2

This example provides a quantum dot light emitting diode (QLED) device. Referring to FIG. 4, the QLED device includes an anode, a hole injection layer, a hole transport layer, a self-assembled molecular layer, a quantum dot light emitting layer, an electron transport layer, and a cathode, which are sequentially stacked on a substrate. The material of the self-assembled molecular layer was R₃-R₄, specifically 2-phenylethoxy acrylate, and had the formula:

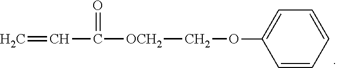

The manufacturing method of the quantum dot light emitting diode device includes the following steps.

A substrate was provided, and an anode was formed on the substrate.

A hole injection layer was formed on the anode.

A hole transport layer was formed on the hole injection layer.

A self-assembled molecular layer was formed on the hole transport layer, and a material of the self-assembled molecular layer is R₃-R₄.

A quantum dot light emitting layer was formed on the self-assembled molecular layer.

An electron transport layer was formed on the quantum dot light emitting layer.

A cathode was formed on the electron transport layer.

In the quantum dot light emitting diode device of this example, in addition to the substrate, the anode, and the cathode, the thin film deposition of each of other functional layers was realized by printing.

### Example 3

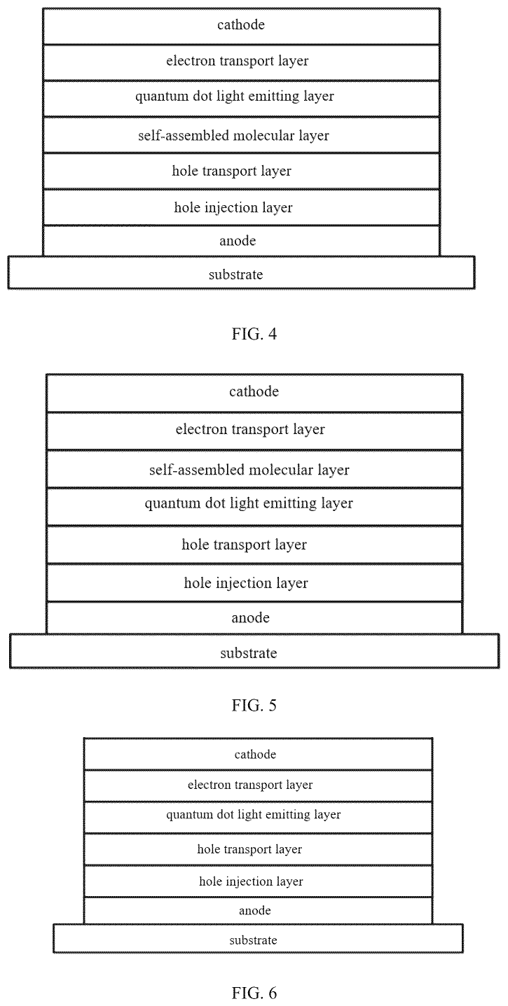

This example provides a quantum dot light emitting diode (QLED) device. Referring to FIG. 5, the QLED device includes an anode, a hole injection layer, a hole transport layer, a quantum dot light emitting layer, a self-assembled molecular layer, an electron transport layer, and a cathode, which are sequentially stacked on a substrate. The material of the self-assembled molecular layer is R₅-R₆, specifically dodecyltrimethoxysilane, and the formula is:

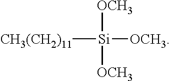

The manufacturing method of the quantum dot light emitting diode device includes the following steps.

A substrate was provided, and an anode was formed on the substrate.

A hole injection layer was formed on the anode.

A hole transport layer was formed on the hole injection layer.

A quantum dot light emitting layer was formed on the hole transport layer;

A self-assembled molecular layer was formed on the quantum dot light emitting layer, and a material of the self-assembled molecular layer is R₅-R₆.

An electron transport layer was formed on the self-assembled molecular layer.

A cathode was formed on the electron transport layer.

In the quantum dot light emitting diode device of this example, in addition to the substrate, the anode, and the cathode, the thin film deposition of each of other functional layers was realized by printing.

### Comparative Example 1

This example provides a quantum dot light emitting diode (QLED) device. Referring to FIG. 6, the QLED device includes an anode, a hole injection layer, a hole transport layer, a quantum dot light emitting layer, an electron transport layer, and a cathode, which are sequentially stacked on a substrate.

The manufacturing method of the quantum dot light emitting diode device includes the following steps.

A substrate was provided, and an anode was formed on the substrate.

A hole injection layer was formed on the anode.

A hole transport layer was formed on the hole injection layer.

A quantum dot light emitting layer was formed on the hole transport layer.

An electron transport layer was formed on the quantum dot light emitting layer.

A cathode was formed on the electron transport layer.

In the quantum dot light emitting diode device of this example, in addition to the substrate, the anode, and the cathode, the thin film deposition of each of other functional layers was realized by printing.

### Test Example 1

This test example compared the QLED devices of Examples 2 to 3 with that of Comparative Example 1 to verify the improved effect of the self-assembled molecular layer of the present disclosure on the performance of the QLED devices.

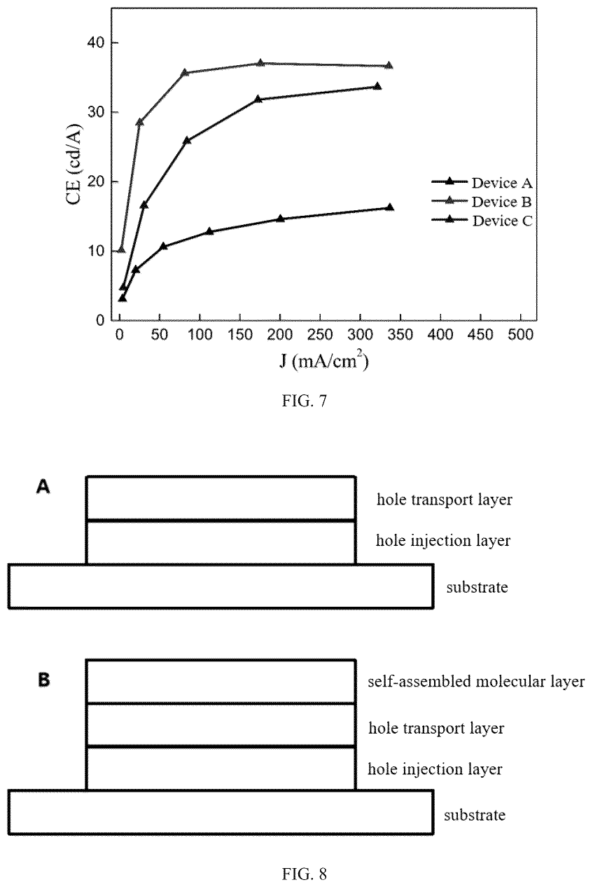

Materials of the hole injection layer, the hole transport layer, the quantum dot light emitting layer, and the electron transport layer in Examples 2 to 3 and Comparative Example 1 were not specifically limited, but the same functional layers of the devices in Examples 2 to 3 and Comparative Example 1 had the same materials and were formed by the same manufacturing processes. The performance results of the devices in Examples 2 to 3 are shown in FIG. 7, in which Comparative Example 1 is denoted as Device A, Example 2 is denoted as Device B, and Example 3 is denoted as Device C.

It can be found that the maximum current efficiencies of device A, device B, and device C are 16.5 cd/A, 37.2 cd/A, 33.4 cd/A, respectively. Obviously, the device current efficiencies of Examples 2 and 3 of the present disclosure are significantly higher than that of Comparative Example 1, thereby indicating that the self-assembled molecular layer of the present disclosure can significantly improve device efficiency.

### Test Example 2

In this test example, it was studied whether the self-assembled molecular layer can effectively reduce the erosion and damage of the hole transport layer film by the solvent of thin film material of the quantum dot light emitting layer and improve the interface bonding.

Method: two fluorescent thin films were provided, one of which was a fluorescent thin film A including a hole injection layer and a hole transport layer which were sequentially stacked on a substrate (see A in FIG. 8), another of which was a fluorescent film B including a hole injection layer, a hole transport layer, and a self-assembled molecular layer, which were sequentially stacked on a substrate (see B in FIG. 8).

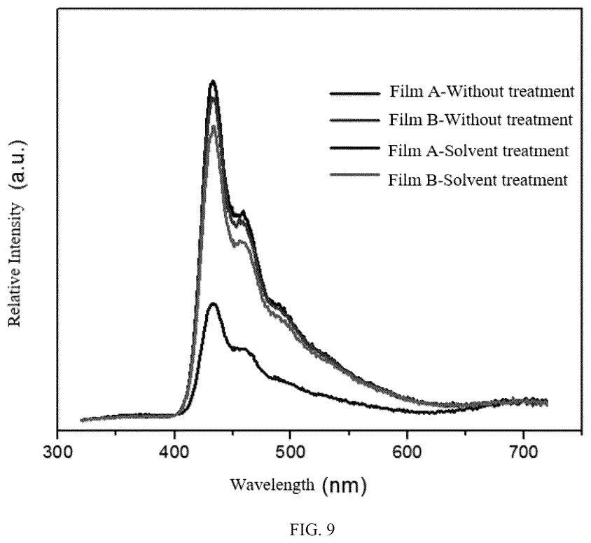

The prepared fluorescent film A and the prepared fluorescent film B were respectively immersed in a solvent of the quantum dot light emitting layer material for 10 min, and then fluorescence emission intensities were measured, as shown in FIG. 9. As shown in FIG. 10, surface roughnesses of the films were tested by AFM to obtain an AFM diagram, so as to indicate the improved effect of the self-assembled monomolecular layer on the solvent erosion of the upper quantum dot light emitting layer material on the lower hole transport film.

As a result, the relative fluorescence intensities of fluorescent film A (without solvent soaking treatment), fluorescent film B (without solvent soaking treatment), fluorescent film A (solvent soaking treatment for 10 min) and fluorescent film B (solvent soaking treatment for 10 min) were 100%, 95%, 35% and 86%, respectively, see FIG. 9. The surface roughnesses Rqs of the four films were 0.491 nm, 0.560 nm, 1.74 nm, and 0.550 nm, respectively, as shown in FIG. 10. It can be seen that the self-assembled molecular layer can effectively reduce the erosion and damage of the solvent of the quantum dot light emitting layer material to the hole transport layer thin film.

### Test Example 3

In this example, it was studied whether the self-assembled molecular layer can effectively reduce the erosion and damage of the quantum dot light emitting layer film by the solvent of thin film material of the electron transport layer thin film and improve the interface bonding.

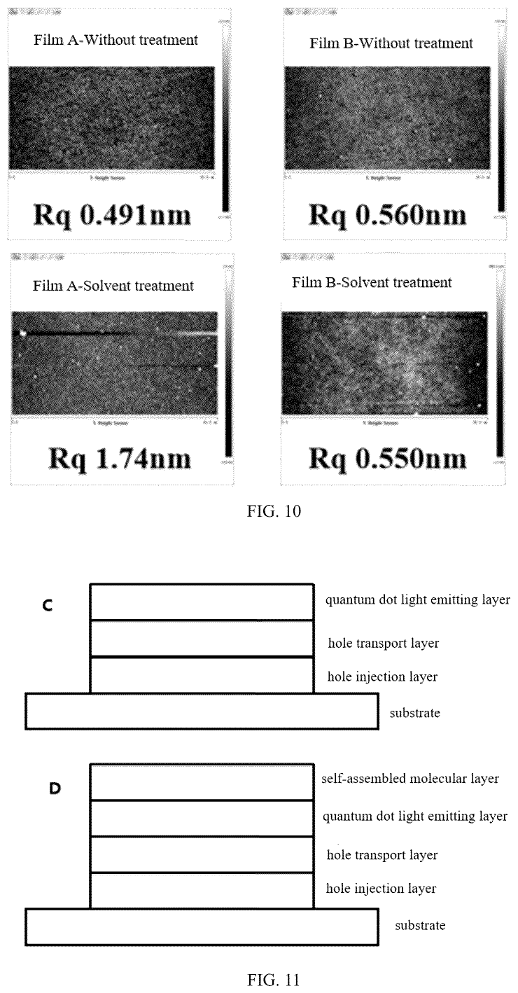

Methods: two fluorescent thin films were provided, one of which is a fluorescent thin film C including a substrate, a hole injection layer, a hole transport layer, and a quantum dot light emitting layer, which were sequentially stacked (see C in FIG. 11), another of which was a fluorescent film D, or a substrate, a hole injection layer, a hole transport layer, a quantum dot light emitting layer, and a self-assembled molecular layer (see D in FIG. 11).

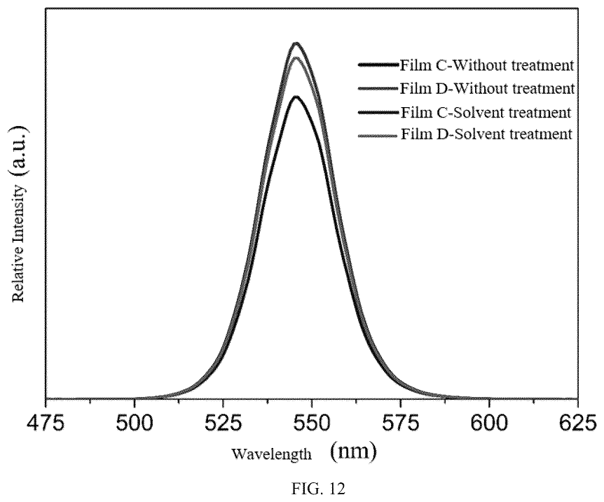

The prepared fluorescent film C and the prepared fluorescent film D were immersed in a solvent of the electron transport layer material for 30 min, respectively, and then fluorescence emission intensities were measured, as shown in FIG. 12.

As a result, the relative fluorescence intensities of the fluorescent film C (without solvent soaking treatment), the fluorescent film D (without solvent soaking treatment), the fluorescent film C (solvent soaking treatment for 30 min), and the fluorescent film D (solvent soaking treatment for 30 min) were 100%, 100.1%, 85%, and 96%, respectively. It can be seen that the self-assembled molecular layer can effectively reduce the erosion and damage of the solvent of the electron transport layer material to the quantum dot light emitting layer film.

In summary, in the present disclosure, in order to improve the problem that the binding force between the functional thin film layer and the quantum dot light emitting layer is poor due to the difference in the material types and characteristics of the organic hole transport material, the inorganic quantum dot material, and the inorganic electron transport material, the positively charged tetravalent nitrogen (N) and R3 in the self-assembled molecular layer can form a strong electrostatic interaction and hydrogen bond with the organic hole transport layer, R₂ and R₄ can only form a van der Waals force adsorption with the hole transport layer but can be combined with the quantum dot light emitting layer in a form of coordination bond or hydrogen bond; alternatively, R5 in the self-assembled molecular layer can be combined with the quantum dot light emitting layer by a coordination bond or a hydrogen bond, and R6 and the quantum dot light emitting layer can only form van der Waals force adsorption, thereby effectively improving the adhesion between the functional transport film layer and the quantum dot light emitting layer, improving the mechanical reliability of the interface, and solving the problem that the solvent of the upper-layer film material erodes and damages the lower-layer film in the process.

In the above-mentioned embodiments, the description of each embodiment has its own emphasis, and parts not described in detail in a certain embodiment may be referred to the related description of other embodiments.

The quantum dot light emitting diode device, a method for manufacturing the same, and a display panel according to embodiments of the present invention are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of application in accordance with the teachings of the present disclosure. In view of the foregoing, the content of the present specification should not be construed as limiting the disclosure.

1. A quantum dot light emitting diode device comprising a first electrode, a hole functional layer, a quantum dot light emitting layer, an electron functional layer, and a second electrode that are stacked in sequence; wherein there is a self-assembled molecular layer arranged between the hole functional layer and the quantum dot light emitting layer, or there is a self-assembled molecular layer arranged between the electron functional layer and the quantum dot light emitting layer, or there are self-assembled molecular layers arranged between the hole functional layer and the quantum dot light emitting layer and between the electron functional layer and the quantum dot light emitting layer respectively.

2. The quantum dot light emitting diode device according to claim 1, wherein the hole functional layer comprises a hole injection layer and/or a hole transport layer; and
the electron functional layer comprises an electron injection layer and/or an electron transport layer.

3. The quantum dot light emitting diode device according to claim 1, wherein the self-assembled molecular layer between the hole functional layer and the quantum dot light emitting layer comprises a compound having a structure represented by a general formula (R₁)₃NR₂X; and
wherein in the general formula (R₁)₃NR₂X, R₁ is methyl or ethyl, N is a positively charged tetravalent nitrogen, X is a halogen anion or carboxylate, R₂ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₂ ranges from 4 to 20.

4. The quantum dot light emitting diode device according to claim 3, wherein there is an electrostatic adsorption force between the positively charged tetravalent nitrogen and unsaturated bonds in the hole functional layer; and
there is a van der Waals force or a hydrogen bond formed between the R₂ and a ligand of a quantum dot of the quantum dot light emitting layer, or there is a coordination bond formed between the R₂ and a quantum dot of the quantum dot light emitting layer.

5. The quantum dot light emitting diode device according to claim 3, wherein the compound having the structure represented by the general formula (R₁)₃NR₂X is selected from:

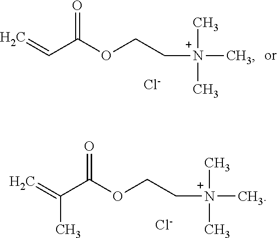

6. The quantum dot light emitting diode device according to claim 1, wherein the self-assembled molecular layer between the hole functional layer and the quantum dot light emitting layer comprises a compound having a structure represented by the general formula R₃-R₄; and
wherein in the general formula R₃-R₄, R₃ is a phenol group or a catechol group; R₄ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₄ ranges from 4 to 20.

7. The quantum dot light emitting diode device according to claim 6, wherein the R₃ forms a hydrogen bond with a surface of the hole functional layer such that the self-assembled molecular layer is bonded to the surface of the hole functional layer; and
wherein there is a van der Waals force or a hydrogen bond between the R₄ and a ligand of a quantum dot of the quantum dot light emitting layer, or there is a coordination bond is formed between the R4 and the quantum dot of the quantum dot light emitting layer, such that the self-assembled molecular layer is bonded to a surface of the quantum dot light emitting layer.

8. The quantum dot light emitting diode device according to claim 6, wherein the compound having the structure represented by the general formula R₃-R₄ is selected from:

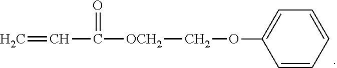

9. The quantum dot light emitting diode device according to claim 1, wherein the self-assembled molecular layer between the quantum dot light emitting layer and the electron functional layer comprises a compound having a structure represented by the general formula R₅-R₆; and
wherein in the general formula R₅-R₆, R₅ is selected from one or more of an amino group, sulfhydryl, carboxyl, hydroxyl, carbonyl, an amide group, phosphorus, phosphorusoxy, organophosphorus, a thioether group, or a polysiloxane group, R₆ is selected from one or more of hydrocarbyl, hydrocarbyl containing an aryl group, or an ether group, a polyoxypropylene group, or a perfluoroalkyl group, and a number of carbon atoms of R₆ ranges from 4 to 20.

10. The quantum dot light emitting diode device according to claim 9, wherein there is a coordination bond formed between the R5 and a quantum dot of the quantum dot light emitting layer, or there is a hydrogen bond formed between the R5 and a surface ligand of the quantum dot of the quantum dot light emitting layer, such that the self-assembled molecular layer is bonded to a surface of the quantum dot light emitting layer; and
there is a van der Waals force between the R₆ and a surface of the electronic functional layer, so that the self-assembled molecular layer is adsorbed to the surface of the electronic functional layer.

11. The quantum dot light emitting diode device according to claim 9, wherein the compound having the structure represented by the general formula R5-R6 is selected from:

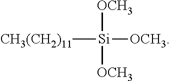

12. The quantum dot light emitting diode device according to claim 1, wherein a thickness of the self-assembled molecular layer ranges from 1 nm to 50 nm.

13. The quantum dot light emitting diode device according to claim 1, wherein the hole functional layer comprises a hole transport layer comprising an organic hole transport material, the organic hole transport material comprises one or more of biphenyl-based material, poly/bithiophene-based material, triarylamine-based material, carbazole-based material, pyrazoline-based material, butadiene-based material, or styrene-based material;
the electron functional layer comprises an electron transport layer, the electron transport layer comprises an inorganic nanoparticle material, and the inorganic nanoparticle material comprises one or more of doped or undoped metal oxides, preferably, the doped or undoped metal oxides comprise one or more of ZnO, TiO₂, SnO₂, Ta₂O₃, ZrO₂, TiLiO, ZnAlO, ZnMgO, ZnSnO, ZnLiO, or InSnO; and
the quantum dot light emitting layer comprises a quantum dot, the quantum dot comprises one or more of a Group II-VI compound or a Group III-V compound, preferably, the quantum dot comprises one or more of CdS, CdSe, CdTe, ZnS, ZnSe, ZnTe, GaAs, GaP, GaSb, HgS, HgSe, HgTe, InAs, InP, InSb, AlAs, AlP, CuInS, or CuInSe.

14. A method of manufacturing a quantum dot light emitting diode device, wherein the method comprises following steps of:
providing a substrate on which a first electrode is formed;
forming a hole functional layer on the first electrode;
forming a quantum dot light emitting layer on the hole functional layer;
forming an electron functional layer on the quantum dot light emitting layer; and
forming a second electrode on the electron functional layer; or
the method comprises following steps of:
providing a substrate on which a second electrode is formed;
forming an electron functional layer on the second electrode;
forming a quantum dot light emitting layer on the electron functional layer;
forming a hole functional layer on the quantum dot light emitting layer; and
forming a first electrode on the hole functional layer;
wherein there is a self-assembled molecular layer arranged between the hole functional layer and the quantum dot light emitting layer, or there is a self-assembled molecular layer arranged between the electron functional layer and the quantum dot light emitting layer, or there are self-assembled molecular layers arranged between the hole functional layer and the quantum dot light emitting layer and between the electron functional layer and the quantum dot light emitting layer respectively.

15. The method according to claim 14, wherein the self-assembled molecular layer between the hole functional layer and the quantum dot light emitting layer comprises a compound having a structure represented by a general formula (R₁)₃NR₂X; and
wherein in the general formula (R₁)₃NR₂X, R₁ is methyl or ethyl, N is a positively charged tetravalent nitrogen, X is a halogen anion or carboxylate, R₂ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₂ ranges from 4 to 20.

16. The method according to claim 14, wherein the self-assembled molecular layer between the hole functional layer and the quantum dot light emitting layer comprises a compound having a structure represented by the general formula R₃-R₄; and wherein in the general formula R₃-R₄, R₃ is a phenol group or a catechol group; R₄ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₄ ranges from 4 to 20.

17. The method according to claim 14, wherein the self-assembled molecular layer between the quantum dot light emitting layer and the electron functional layer comprises a compound having a structure represented by the general formula R₅-R₆; and
wherein in the general formula R₅-R₆, R₅ is selected from one or more of an amino group, sulfhydryl, carboxyl, hydroxyl, carbonyl, an amide group, phosphorus, phosphorusoxy, organophosphorus, a thioether group, or a polysiloxane group, R₆ is selected from one or more of hydrocarbyl, hydrocarbyl containing an aryl group, or an ether group, a polyoxypropylene group, or a perfluoroalkyl group, and a number of carbon atoms of R₆ ranges from 4 to 20.

18. A display panel comprising a substrate and quantum dot light emitting diode devices disposed on a surface of the substrate in an array, wherein each of the quantum dot light emitting diode devices comprises a first electrode, a hole functional layer, a quantum dot light emitting layer, an electron functional layer, and a second electrode that are stacked in sequence; and wherein there is a self-assembled molecular layer arranged between the hole functional layer and the quantum dot light emitting layer, or there is a self-assembled molecular layer arranged between the electron functional layer and the quantum dot light emitting layer, or there are self-assembled molecular layers arranged between the hole functional layer and the quantum dot light emitting layer and between the electron functional layer and the quantum dot light emitting layer respectively.

19. The display panel according to claim 18, wherein the self-assembled molecular layer between the hole functional layer and the quantum dot light emitting layer comprises a compound having a structure represented by a general formula (R₁)₃NR₂X; and wherein in the general formula (R₁)₃NR₂X, R₁ is methyl or ethyl, N is a positively charged tetravalent nitrogen, X is a halogen anion or carboxylate, R₂ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₂ ranges from 4 to 20; or
the self-assembled molecular layer between the hole functional layer and the quantum dot light emitting layer comprises a compound having a structure represented by the general formula R₃-R₄; and wherein in the general formula R₃-R₄, R₃ is a phenol group or a catechol group; R₄ is selected from one or more of hydrocarbyl, hydrocarbyl containing an aryl group, hydroxy, sulfhydryl, an ester group, an ether group, an amine group, an amide group, phosphorus, phosphorusoxy or a thioether group, a polyoxypropenyl group, a perfluoroalkyl group, or a polysiloxanyl group, and a number of carbon atoms of R₄ ranges from 4 to 20.

20. The display panel according to claim 18, wherein the self-assembled molecular layer between the quantum dot light emitting layer and the electron functional layer comprises a compound having a structure represented by the general formula R₅-R₆; and wherein in the general formula R₅-R₆, R₅ is selected from one or more of an amino group, sulfhydryl, carboxyl, hydroxyl, carbonyl, an amide group, phosphorus, phosphorusoxy, organophosphorus, a thioether group, or a polysiloxane group, R₆ is selected from one or more of hydrocarbyl, hydrocarbyl containing an aryl group, or an ether group, a polyoxypropylene group, or a perfluoroalkyl group, and a number of carbon atoms of R₆ ranges from 4 to 20.
